(19) United States
(12) Patent Application Publication
(10) Pub. No.: US 2024/0088098 A1
(43) Pub. Date: Mar. 14, 2024

(54) HYBRID MEMORY ARCHITECTURE FOR ADVANCED 3D SYSTEMS

(71) Applicant: Advanced Micro Devices, Inc., Santa Clara, CA (US)

(72) Inventors: Divya Madapusi Srinivas PRASAD, Mountain View, CA (US); Niti MADAN, Bee Cave, TX (US); Michael IGNATOWSKI, Austin, TX (US); Hyung-Dong LEE, Austin, TX (US)

(21) Appl. No.: 18/199,837

(22) Filed: May 19, 2023

Related U.S. Application Data
(60) Provisional application No. 63/405,347, filed on Sep. 9, 2022.

(51) Int. Cl. H01L 25/065; H10B 80/00

(52) U.S. Cl. CPC H01L 25/0657; H10B 80/00; H01L 2225/06503

(57) ABSTRACT

Disclosed wherein stacked memory dies that utilize a mix of high and low operational temperature memory and non-volatile based memory dies, and chip packages containing the same. High temperature memory dies, such as those using non-volatile memory (NVM) technologies are in a memory stack with low temperature memory dies, such as those having volatile memory technologies. In some cases, the high temperature memory technologies could be used together, in some cases, on the same IC die as logic circuitry. In one example, a memory stack is provided that include a first memory IC die having high temperature memory circuitry, such as non-volatile memory, stacked below a second memory IC die. The second memory IC die has high temperature memory circuitry, such as volatile memory circuitry.

### CROSS REFERENCE TO RELATED APPLICATIONS

This application claims benefit from U.S. Provisional Patent Application No. 63/405,347, filed Sep. 9, 2022, which is incorporated by reference in its entirety.

### TECHNICAL FIELD

Embodiments of the invention generally relate to stacked memory dies having volatile and non-volatile based memory dies, and chip packages containing the same.

### BACKGROUND

The memory wall (i.e., bandwidth limitations) has been referred to as one of the key limiters in pushing the bounds of computation in modern systems. High bandwidth memory (HBM) and other stacked dynamic random-access memory (DRAM) memories have been proposed/enabled to alleviate off-chip memory access latency as well as increase memory density. In addition to the traditional DRAM roadmap, several other memories are being explored, that have not yet reached maturity for large scale manufacturing, e.g., technologies such as ferro-electric random-access memory (FeRAM), magneto resistive random-access memory (MRAM), phase-change memory (PCM), etc. During this technology enablement phase, it is crucial to not only examine how new technologies would “replace” the classic roadmap, but if it can aid/complement/address the limitations of existing DRAM without adding much complexity, or how it can be used together with existing technologies to enhance specific properties to achieve superior system on a chip (SoC) performance and power efficiency.

Memory wall problems are currently being tackled by the industry with HBM-like solutions. Stacked DRAM and HBM as described in the JEDEC Solid State Technology Association (e.g., JEDEC) specifications address memory bandwidth and latency issues by replacing long off-chip connections with stacked (e.g., connected through silicon interposers) memory closer to the logic die. However, there exist yield challenges and overhead due to the non-linear power increase with memory capacity increase. Additionally, 3D stacking on logic, brings new thermal challenges that can negatively impact retention in DRAM. On the other hand, other non-volatile memory (NVM) technologies like logic-compatible FeRAM do not have refresh-requirements and can tolerate high temperature; but suffer with scalability/large capacity and wearout, while static random-access memory (SRAM) is a faster but leaky memory system. Current solutions do not fully utilize hybrid memory systems as disclosed by the inventors herein to take advantage of the unique properties of each memory type; hence do not maximize performance/power-efficiency potential.

Non-volatile main memories such as FeRAMs, MRAMs, and volatile memories such as DRAMs (including HBM and other stacked variants of DRAM) are being considered and traded-off for achieving higher memory density, performance, and lower power.

DRAMs have been the most popular off-chip memory, however, even Double Data Rate 5 Synchronous DRAM (DDR5) has certain Performance-Power-Area (PPA) limitations of having to going off-chip to access data. The typical DRAM bitcell consists of a one transistor and one capacitor (1T-1C) structure where the capacitor is formed by a dielectric layer sandwiched in between conductor plates. System interprocess communication (IPC) is often limited by DRAM bandwidth and latency, especially in memory-heavy workloads. HBM has been introduced to provide increased bandwidth and memory density, allowing up to 8-12 layers of DRAM dies to be stacked on top of each other with an optional logic/memory interface die. This memory stack can either be connected to the CPU/GPU through silicon interposers (FIG. 1) or placed on top of the CPU/GPU themselves to provide superior connectivity and performance.

FeRAM is like 1T-1C DRAM, except for that the capacitor is made of a ferroelectric material versus a (linear) dielectric as used in DRAM. Bit ‘0’ and ‘1’ are written with electric polarization orientations of the ferroelectric material in the dielectric. The benefit of this technology is refresh-free storage which has potential to offer more density and performance over DRAM.

MRAM on the other hand has a one transistor and one resistor (1T-1R) bitcell. Unlike DRAM and FeRAM, MRAM does not have a destructive read. However, MRAM is less reliable compared to FeRAM and has lower endurance and retention.

Typically, the memory technology is developed and “optimized” as an independent macro or for specific applications like deep neural networks (DNN), in the HBM case. Albeit some advancements like graphics double data rate (GPDDR) vs double data rate (DDR) have been developed to support high-bandwidth memory for graphics applications. More fine-grained optimizations of memory technology with logic technology and architecture are not deeply explored, and there is much to do to achieve superior performance and lower power products. Non-linear power increase and decreasing improvement in performance and memory density from generation to generation requires more design and co-optimization to push alleviate the memory bottleneck.

### SUMMARY

Disclosed wherein stacked memory dies that utilize a mix of high and low operational temperature memory and non-volatile based memory dies, and chip packages containing the same. High temperature memory dies, such as those using non-volatile memory (NVM) technologies are in a memory stack with low temperature memory dies, such as those having volatile memory technologies. In some cases, the high temperature memory technologies could be used together, in some cases, on the same IC die as logic circuitry. In one example, a memory stack is provided that include a first memory IC die having high temperature memory circuitry, such as non-volatile memory, stacked below a second memory IC die. The second memory IC die has high temperature memory circuitry, such as volatile memory circuitry.

In another example, a memory stack is provided that includes a first memory IC die stacked on a second memory IC die. The first memory IC die includes memory circuitry that requires more frequent refresh rates as compared the second memory IC die. In some other examples, the first memory IC die includes memory circuitry operational at temperatures above 110 degrees Celsius without increased refresh rates as compared to operation at 95 degrees Celsius. The second memory IC die includes memory circuitry requiring increased refresh rates at temperatures above 110 degrees Celsius as compared to operation at 95 degrees Celsius.

In another example, a memory stack is provided that includes a first memory IC die stacked on a second memory IC die. The first memory IC die includes ferro-electric random-access memory (FeRAM). The second memory IC die includes dynamic random-access memory (DRAM) circuitry.

In yet another example, a chip package having a memory stack mounted to a package substrate is provided. The memory stack that includes a plurality of first memory IC dies stacked on a second memory IC die. The second memory IC die includes ferro-electric random-access memory (FeRAM) circuitry and optionally controller circuitry. The second memory IC die is stacked on the package substrate. The plurality of first memory IC dies includes DRAM circuitry.

Also disclosed herein are non-volatile memory (NVM) technologies, that may be utilized in a memory stack with volatile memory technologies. In some cases, the NVM technologies could be used together, in some cases on the same IC die as logic circuitry. Exploitation of specific properties of each of the technologies, in the stacked memory subsystem, can beneficially result in differentiated SoC performance.

In one example, a memory stack is provided that include a first memory IC die having non-volatile memory (NVM) circuitry stacked below a second memory IC die. The second memory IC die has volatile memory circuitry.

In another example of a memory stack, one IC memory die of the memory stack includes ferro-electric random-access memory (FeRAM) or static random-access memory (SRAM) circuitry, while another IC memory die of the memory stack includes volatile memory circuitry.

In another example of a memory stack, one IC memory die of the memory stack includes ferro-electric random-access memory (FeRAM) or static random-access memory (SRAM) circuitry, while another IC memory die of the memory stack includes dynamic random-access memory (DRAM) circuitry.

In another example of a memory stack, first processing in memory (PIM) circuitry is disposed in a second memory IC die of the memory stack while a second PIM circuitry is disposed in the third memory IC die of the memory stack.

In another example of a memory stack, a first buffer IC die disposed between one pair of memory IC dies, a second buffer IC die disposed between another pair of memory IC dies.

In another example, memory stack includes a first memory IC die comprising first ferro-electric random-access memory (FeRAM) circuitry and first processing in memory (PIM) circuitry, a second memory IC die stacked on the first memory IC die, and a third memory IC die stacked on the first memory IC die. The second memory IC die includes second FeRAM circuitry and second PIM circuitry. The third memory IC die includes third FeRAM circuitry and third PIM circuitry.

In yet another example, a chip package is provided that includes a hybrid memory stack mounted on a substrate. The hybrid memory stack include both volatile and non-volatile memory IC dies.

### BRIEF DESCRIPTION OF THE DRAWINGS

FIG. 1 depicts a chip package having a memory stack connected to a compute/processor die through an interposer.

FIG. 2 depicts an IC die stack disposed on top of a compute/processor chip and a memory-interface/controller die.

FIG. 3A depicts a high-temperature memory die stacked on top of a compute/processor chip and a memory-interface/controller die.

FIG. 3B depicts a high-temperature memory, a compute/processor circuitry and memory-interface/controller circuitry integrated into a single integrated circuit (IC) die.

FIG. 4A is a memory die stack disposed on top of a compute/processor chip and a memory-interface/controller die, the memory die stack including at least one low temperature memory integrated circuit die and at least one high temperature memory integrated circuit die.

FIG. 4B is a memory die stack disposed on top of a compute/processor chip, the memory die stack including at least one low temperature memory integrated circuit die and at least one high temperature memory integrated circuit die, wherein the high temperature memory integrated circuit die includes controller circuitry.

FIG. 4C is a memory die stack disposed on top of a compute/processor chip and a memory-interface/controller die, the memory die stack including at least one low temperature memory integrated circuit die and at least one high temperature memory integrated circuit die having a buffer IC die disposed therebetween, the buffer IC including logic and non-volatile memory circuitry.

FIG. 5A is a memory die stack disposed on top of a compute/processor chip and a memory-interface/controller die, the memory die stack including a plurality of low temperature memory integrated circuit dies, one of more of the low temperature memory integrated circuit dies having processing in memory (PIM) circuitry with FeRAM and/or embedded DRAM based PIM local storage.

FIG. 5B is a memory die stack disposed on top of a compute/processor chip and a memory-interface/controller die, the memory die stack including a plurality of low temperature memory integrated circuit dies, one of more of the low temperature memory integrated circuit dies having additional PIM circuitry relative to FeRAM and/or embedded DRAM based PIM storage as compared to the memory die stack of FIG. 5A.

FIG. 5C is a memory die stack disposed on top of a compute/processor chip and a memory-interface/controller die, the memory die stack including a plurality of low temperature memory integrated circuit dies, one of more of the low temperature memory integrated circuit dies having fine grained PIM circuitry with FeRAM and/or embedded DRAM based PIM local storage.

FIG. 5D is a memory die stack disposed on top of a compute/processor chip and a memory-interface/controller die, the memory die stack including a plurality of high temperature memory integrated circuit dies, one of more of the high temperature memory integrated circuit dies having fine grained sub-bank level PIM circuitry with FeRAM based PIM local storage.

### DETAILED DESCRIPTION

The disclosure herein addresses specific challenges of stacked DRAM subsystem with hybrid memory 3D organization and logic codesign. The disclosed technology defines various methods, systems and devices to design compute- and application-aware advanced memory-based systems. Generally, disclosed are memory die stacks that utilize a mix of high and low operational temperature memory dies such that the high temperature die may function as a temperature buffer with adjacent heat generating logic dies. In particular, disclosed are memory die stacks that utilize a mix of volatile and non-volatile based memory dies, one example of which are stacked DRAM and FeRAM based memory die.

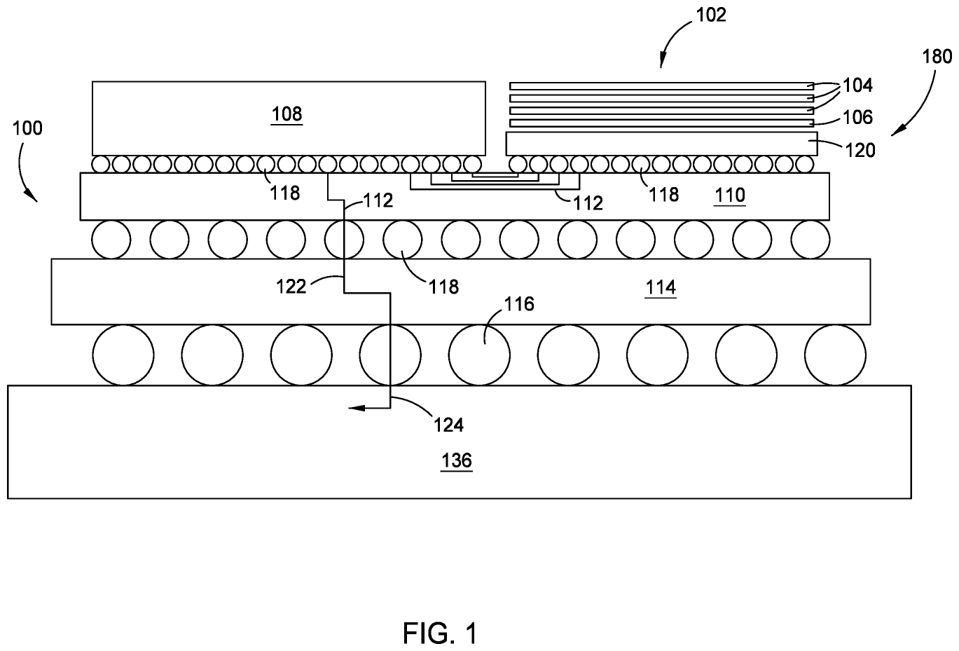

FIG. 1 depicts a chip package 100 having a memory stack 102 connected to a compute/processor IC die 108 through an interposer 110. Any of the memory stacks described herein may be utilized in the chip package 100 depicted in FIG. 1, or other suitable memory device. The chip package 100 depicted in FIG. 1, which may include any of the other memory stacks described below, also includes a package substrate 114 to which the interposer 110 is mounted. The package substrate 114 of the chip package 100 may be coupled to a printed circuit board (PCB) 136 to form an electronic system 180, such as but not limited to the graphics card depicted in FIG. 1.

The memory stack 102 generally includes at least one low temperature memory integrated circuit (LTMIC) die 104 stacked with at least one high temperature memory IC (HTMIC) die 106. The space shown in FIG. 1 between the dies 104, 106 is used to make solder connections (not shown) between the dies 104, 106. Alternatively, the dies 104, 106 may be stacked directly in contact with each other using hybrid bonding techniques. The HTMIC and LTMIC dies 106, 104 may be comparatively defined by at least one the following definitions. In one example, a HTMIC die 106 has a memory refresh requirement that is longer than another memory die in the memory stack 102, the memory die having the shorter memory refreshes requirement comparatively referred to the LTMIC die 104. In another example, a HTMIC die 106 has a longer period between refresh (i.e., a longer refresh period) than recommended by Joint Electron Device Engineering Council (JEDEC) Solid State Technology Association standard JESD21-C, the memory die having memory refresh requirements following JESD21-C comparatively referred to as the LTMIC die 104. In another example, the HTMIC die 106 has a memory refresh requirement that exceeds 60 microseconds between memory refreshes, the memory die requiring a memory refresh every 60 microseconds comparatively referred to the LTMIC die 104. In yet another example, In another example, the HTMIC die 106 is non-volatile memory, while the LTMIC die 104 is volatile memory. In still other examples, the LTMIC die 104 can be defined as a memory die that can operate at temperatures up to 110 degrees Celsius (i.e., operational temperature) without having to increase the refresh rate. At temperatures above 110 degrees Celsius, LTMIC die 104 require increased the refresh rates as compared to operation at 110 degrees Celsius (as compared to operation at 95 degrees Celsius). An example of a LTMIC die 104 is a dynamic random-access memory (DRAM) die. Other examples of LTMIC dies 104 include volatile memory dues such as system random-access memory (SRAM), among others.

In still other examples, the HTMIC die 106 has an operational temperature that is greater than the operational temperature of the LTMIC die 104. Defined differently, the HTMIC die 106 is a memory die that can operate at temperatures above 110 degrees Celsius without having to increase the refresh rate (as compared to operation at 95 degrees Celsius). An example of a HTMIC die 106 is a ferromagnetic random-access memory (FeRAM) die. Other examples of HTMIC die 106 include non-volatile memory dues such magnetoresistive random-access memory (MRAM), phase-change memory (PCM), flash memory, and resistive random-access memory (RRAM), among others.

The memory stack 102 may optionally include at least one controller IC die 120 stacked with the LTMIC die 104 and the HTMIC die 106. The IC dies 104, 106, 120 may be electrically and mechanically connected by solder balls and/or hybrid bonding techniques, such that the functional circuitries with in the IC dies 104, 106, 120 can communicate with each other and/or transmit data signals, power and/or ground therethrough.

The functional circuitries within the IC memory dies 104, 106 are arranged into multiple memory banks. Each bank has multiples rows and each row has multiple columns. Residing at each unique memory location within a bank is a memory cell. The memory cell may be addressed using its unique identifying row and cell location within a particular bank of the memory dies 104, 106.

The functional circuitries within the IC dies 104, 106, 120 are coupled to the functional circuitry of the compute/processor IC die 108 via routings 112 formed in the interposer 110. The routings 112 of the interposer 110 are connected to the functional circuitries with in the IC dies 104, 106, 120 via solder connections 118. The routings 112 of the interposer 110 also connect to the functional circuitries of the IC dies 108, 120 to routing 122 formed in the package substrate 114 via the solder connections 118. Solder balls 116 are utilized to connect the routings 122 of the package substrate 114 with routing 124 formed in the PCB 136.

In other embodiments where an interposer is not present, the chip stack 102 and IC die 108 may be mounted directly to the package substrate 114.

The IC die 120 is generally a heat generating device. That is, the IC die 120 generates heat when in use. As the performance of the LTMIC die 104 may be diminished due to the heat generated by the IC die 120, performance of the chip package 100 is enhanced by separating the LTMIC die 104 from the heat generating IC die 120 by one or more HTMIC dies 106. Since the HTMIC die 106 is generally more heat resistant than the LTMIC dies 104, the HTMIC die 106 can be located adjacent the heat generating IC die 120 without significant reduction in performance while enabling the LTMIC dies 104 that are significantly spaced from the heat generating IC die 120 to also maintain robust levels of performance.

In the example depicted in FIG. 1, the chip stack 102 includes one HTMIC die 106 disposed between a plurality of LTMIC die 104 and the controller IC die 120. Although four IC memory dies 104, 106 are illustrated in the single chip stack 102 shown in FIG. 1, the number of LTMIC dies 104 and the number of HTMIC dies 106 comprising the chip stack 102 may vary from one to as many as can fit within the chip package 100. Additionally, although only one chip stack 102 is shown in FIG. 1, one or more additional chip stacks may be disposed adjacent the chip stack 102 shown in FIG. 1.

The controller IC die 120 include functional logic circuitry provides commands that enable the row and column identifying each bank of the memory dies 104, 106 to be addressed. The controller IC die 120 controls the write/read operation from each memory bank.

The HBM memory can be put in low power modes by row address bus to save power on the I/O drivers. To further reduce power consumption, clocks can be gated when in power-down or self-refresh modes.

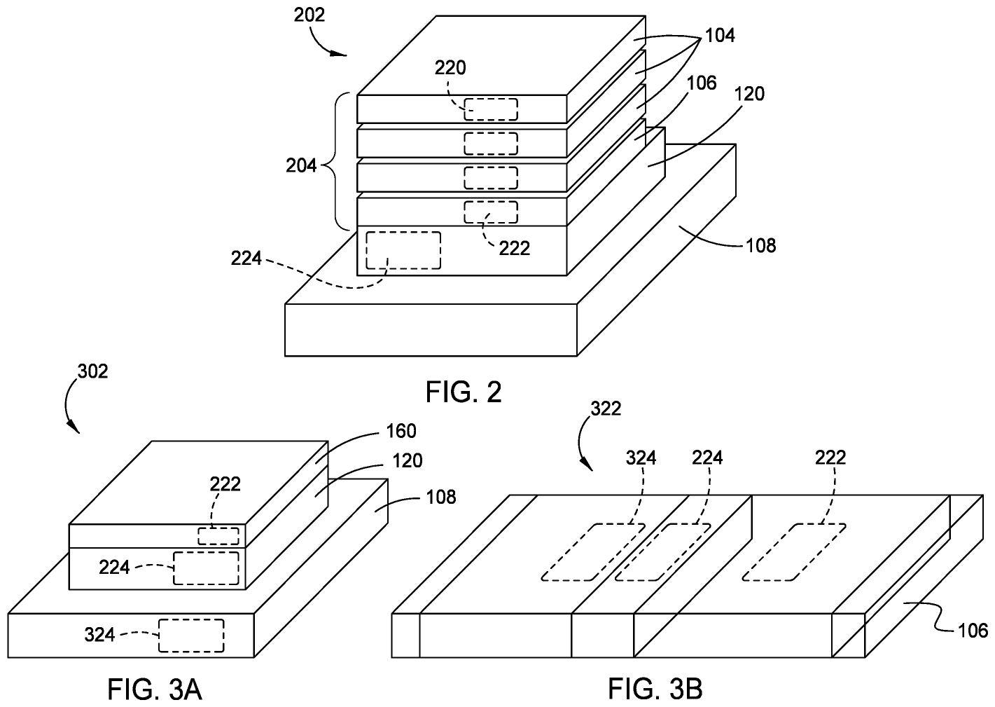

FIG. 2 depicts an IC die stack 202 disposed on top of a compute/processor IC die 108 and a memory-interface/controller IC die 120. The IC die stack 202 may be used in place of the IC die stack 102 and mounted on the interposer 110 or the package substrate 114 in the chip package 100 and electronic system 180 illustrated in FIG. 1.

In the example depicted in FIG. 2, the IC die stack 202 that can be used in the electronic system 180 includes high-bandwidth (HBM) cube 204 stacked on top of the compute IC die 108 and the controller IC die 120. The compute IC die (e.g., compute chip) 108 may be a central processing unit (CPU), graphics processing unit (GPU), field programmable gate array (FPGA), or other accelerator. The HBM cube 204 includes a plurality of LTMIC dies 104 that are vertically stacked. Each LTMIC die 104 includes functional circuitry configured as memory circuitry 220. In one example, the memory circuitry 220 is configured as volatile memory circuitry such as dynamic random-access memory (DRAM) and system random-access memory (SRAM), among others. In an example where the memory circuitry 220 is configured as DRAM circuitry, the LTMIC dies 104 may be referred as DRAM IC dies. The stacked DRAM IC dies may be connected by solder connections, hybrid bonding or other suitable connection. Although 3 DRAM IC die are illustrated in the HBM cube 204 depicted in FIG. 2, the HBM cube 204 may alternatively have more or less than 3 DRAM IC dies.

Sandwiched between the LTMIC dies 104 and the controller IC die 120 in the HBM cube 204 is one or more HTMIC dies 106. In FIG. 2, one HTMIC dies 106 is shown, although more may be utilized. The HTMIC die 106 includes functional circuitry configured as memory circuitry 222. In one example, the memory circuitry 222 is configured as non-volatile random-access memory, such as ferroelectric random-access memory (FeRAM), magnetoresistive random-access memory (MRAM), phase-change memory (PCM), flash memory, and resistive random-access memory (RRAM), among others. In an example where the memory circuitry 222 is configured as FeRAM, the HTMIC die 106 may be referred as a FeRAM IC die.

The memory circuitry 222 of the HTMIC die 106 has an operational temperature that is greater than the operational temperature of the memory circuitry 220 of the LTMIC die 104. Defined differently, the memory circuitry 222 of the HTMIC die 106 is memory circuitry that can operate at temperatures above 110 degrees Celsius without having to increase the refresh rate (as compared to operation at 95 degrees Celsius), while the memory circuitry 220 of the LTMIC die 104 is memory circuitry that cannot operate at temperatures above 110 degrees Celsius without having to increase the refresh rate (as compared to operation at 95 degrees Celsius)

In one example, the HTMIC die 106 is a non-volatile random-access memory IC die that has faster refresh speed as compared to the LTMIC dies 104 that have volatile random-access memory. Thus, in addition to the HTMIC die 106 performing better than the LTMIC dies 104 when placed closer to the controller IC die 120, the faster refresh speed enables faster communication with the controller IC die 120, which beneficially reduces latency within the IC die stack 202, and ultimately, the chip package 100 and the electronic system 180.

In the example depicted in FIG. 2, the HTMIC die 106 has memory circuitry 222 configured a FeRAM circuitry, while the LTMIC dies 104 have memory circuitry 220 configured as DRAM circuitry.

FIG. 3A depicts another example of a memory stack 302 that includes a HTMIC die 106 stacked on top of a compute/processor IC die 108 and a memory-interface/controller IC die 120. Although not shown in FIG. 3A, a plurality of LTMIC dies 104 may be stacked on the HTMIC die 106 shown in FIG. 3A, such as in the manner illustrated in FIG. 2, to complete the memory stack 322. The IC die stack 302 may be used in place of the IC die stack 102 and mounted on the interposer 110 or the package substrate 114 in the chip package 100 and electronic system 180 illustrated in FIG. 1. In the example depicted in FIG. 3A, the HTMIC die 106 includes memory circuitry 222 configured as FeRAM circuitry. In the example depicted in FIG. 3A, the HTMIC die 106 is vertically stacked on top of the memory-interface/controller IC die 120, while the memory-interface/controller IC die 120 is vertically stacked on top of the compute/processor IC die 108. The memory circuitry 222 of the HTMIC die 106 includes FeRAM or other suitable circuitry which is compatible with the controller circuitry 224 of the memory-interface/controller IC die 120. The interconnections between the dies 104, 106, 108, 120 may be made by solder connections, hybrid bonding or other suitable connection. The HTMIC die 106 stacked on top of the compute/processor IC die 120 forms a hybrid memory-logic assembly that may be later stacked with LTMIC dies 104, such as illustrated in FIG. 2.

FIG. 3B depicts another example of a memory stack 322 that includes memory circuitry 222, a compute/processor circuitry 324 and memory-interface/controller circuitry 224 integrated into a single HTMIC die 106. Although not shown in FIG. 3B, a plurality of LTMIC dies 104 may be stacked on the HTMIC die 106 shown in FIG. 3B, such as in the manner illustrated in FIG. 2, to complete the memory stack 322. The additional dies stacked on the HTMIC dies 106 shown in FIG. 3B may be one or more FeRAM dies, and/or one or more LTMIC dies 104 (such as DRAM IC dies), and/or one or more other type of memory dies. In one example, the memory circuitry 222 is configured as FeRAM circuitry, which is compatible with the memory-interface/controller circuitry 224 so that the circuitries 222, 224 may be co-located within the same HTMIC die 106. Similarly, the FeRAM circuitry 222 is also compatible with the compute/processor circuitry 324 so that the circuitries 222, 324, 224 may be co-located within the same HTMIC die 106. In one example, the memory circuitry 222 is disposed between the compute/processor circuitry 324 and the memory-interface/controller circuitry 224. Optionally, the compute/processor circuitry 224 may reside in an IC die neighboring the HTMIC die 106 that contains both the FeRAM and controller circuitries 222, 224.

The advanced memory technology roadmap targets increased memory density and bandwidth, with minimal impact to power and performance to alleviate the memory-bottleneck to system performance. With the advancement in memory technology, memory stacking and novel non-volatile memories like FeRAMs, updating circuitry, architecture and memory interfacing principles keeping in pace with the memory technology itself is imperative. Improvements to memory technology are described below that leverage enhancements specific to HBM/other forms of stacked high temperature memory by integrating low temperature memory technology to create hybrid memory stacks. In one example, stacked DRAM memory may be integrate FeRAM based memory to form a hybrid memory stack or hybrid memory-logic assembly.

Hybrid memory and hybrid memory-logic assembly are disclosed that utilizes a mix of memory technologies that can be stacked, for example on top of a logic die. For example, a hybrid memory cube with a non-volatile memory (such as FeRAM and the like) IC die and a volatile memory (such as DRAM IC and the like) die has the HTMIC die 106 beneficially disposed closest to the logic IC die 120, as the HTMIC die 106 can tolerate higher heat dissipated from the logic-die, while the LTMIC dies 104 disposed on top of the HTMIC die 106 could be placed closer to the heat spreader in the chip package (such as the chip package 100 depicted in FIG. 1) to minimize temperature gradients and impact on performance and refresh rates associated with the LTMIC dies 104.

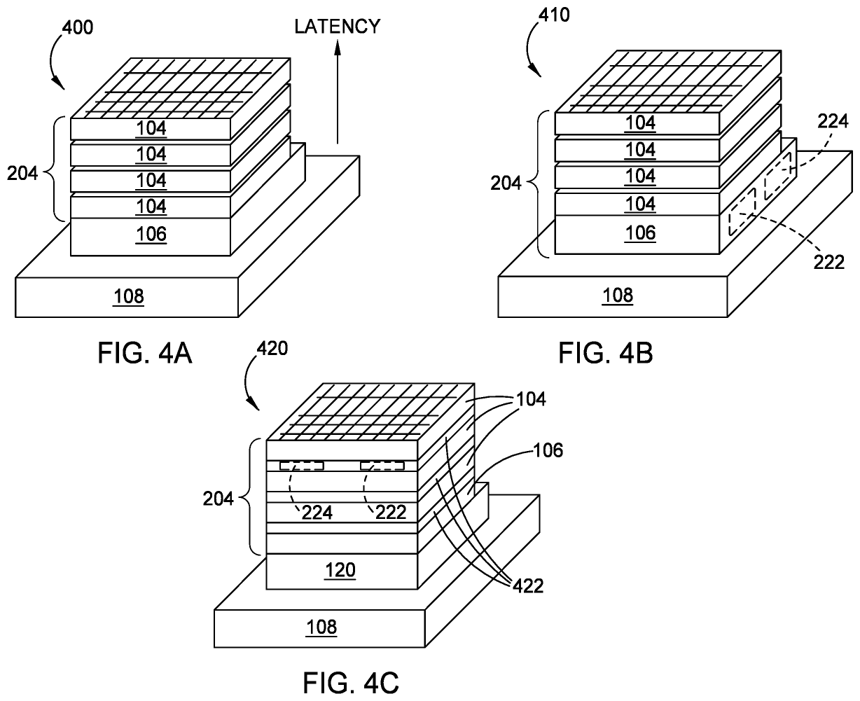

FIG. 4A depicts an example of a memory die stack 400 disposed on top of a compute/processor IC die 108 and a memory-interface/controller IC die 120. The memory die stack 400 includes at least one HTMIC die 106, such as a non-volatile memory IC die, and a plurality of LTMIC dies 104, such as volatile memory dies. Another alternative hybrid approach is to arranged the and HTMIC and LTMIC dies 106, 104 within the same memory die stack 400 ranked based on latency, with the fastest dies being closer to the memory-interface/controller IC die 120. The ranked memory IC dies 104, 106 may include SRAM, DRAM, and non-volatile memory (NVM) IC dies arranged by latency all in the same memory die stack 400. This results in a hierarchical hardware managed cache for the LTMIC dies 104, such as DRAM IC dies, within the stacked memory cube, e.g., the memory die stack 400.

FIG. 4B is a memory die stack 410 disposed on top of a compute/processor IC die 108. The memory die stack 410 includes at least one HTMIC die 106, such as a non-volatile memory IC die, and a plurality of LTMIC dies 104, such as volatile memory dies. The HTMIC die 106 of the memory die stack 410 includes both memory circuitry 222 and controller circuitry 224. For example, the memory circuitry 222 of the HTMIC die 106 may include FeRAM (or other non-volatile memory) circuitry and controller circuitry 224 integrated on the same die. Such an arrangement is illustrated in the memory die stack 410 of FIG. 4B which is enabled by the FeRAM configuration of the memory circuitry 222 being compatible with the logic technology of the controller circuitry 224.

Alternatively, the 10/SA logic on each memory die 104 could be separated into a buffer IC die 422, to achieve higher performance and yield, and could also include FeRAM memory blocks that are logic compatible. Such an example is illustrated in FIG. 4C which shows a memory die stack 420 disposed on top of a compute/processor IC die 108 and a memory-interface/controller IC die 120, the memory die stack 420 including at least one HTMIC die 106, such as a non-volatile memory IC die, and at least one LTMIC die 104, such as a volatile memory die, having buffer IC dies 422 disposed therebetween. The buffer IC die 422 includes both logic and non-volatile memory circuitry 224, 222. The buffer IC die 422 may be hybrid bonded on each side to the other dies 104 comprising the HBM cube 204 of the die stack 420.

Memory stack and technology may be selected and design in a “hierarchical” manner (hardware managed cache), to use the faster memory/or memories not requiring refresh, closer to the logic IC die 120, to act as an “intermediate” layer, to transfer data to more dense, slower memories on the upper tiers of LTMIC dies 104, away from the logic IC die 120. This could help hiding latency, and overhead due to refresh needed for LTMIC dies 104, such as DRAM IC dies, on the top of the memory die stack 420.

In cases where FeRAM or other non-volatile memory dies are used with multi-bit cell storage, (e.g., NAND flash stores multiple bits in one cell), wear out can become a concern, since each cell will be accessed “n” times, where “n” is the number of bits in a single cell, compared to a single bit cell scenario. Hence, DRAM/SRAM and other volatile memories which have enhanced endurance can be used as a “standby” or hardware managed cache for the non-volatile memory dies. This allows multiple writes (termed write levelling) to be combined to a single write into the non-volatile memory multi-bit cell, which beneficially reduces the number of writes to a single cell in the non-volatile memory IC die and increases the lifetime of the non-volatile memory circuitry. Reads may be combined in substantially the same manner.

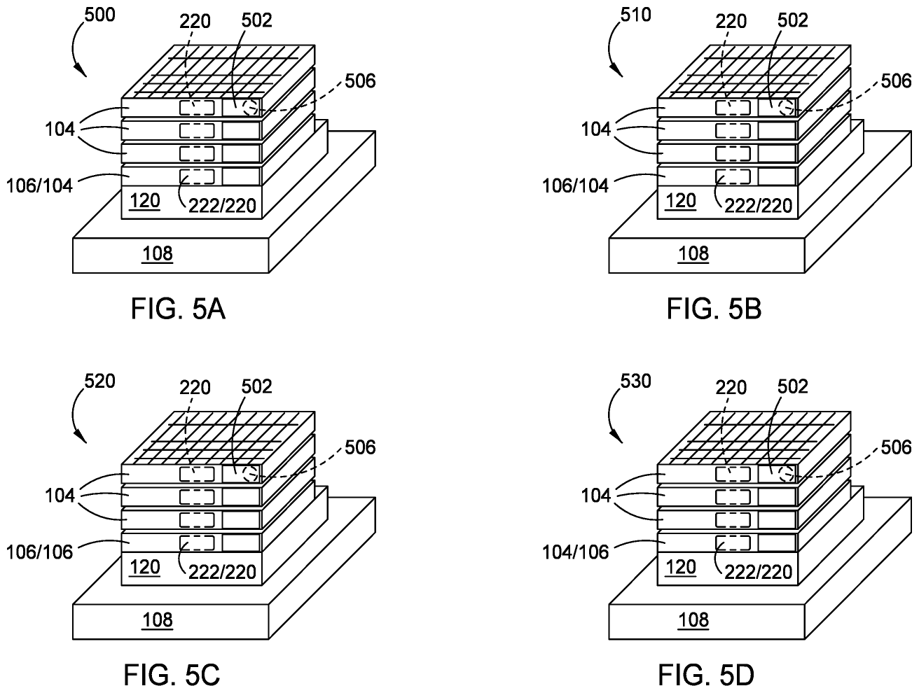

FIGS. 5A through 5D illustrate some non-limiting examples of processing in memory (PIM) circuitry 502 utilized within hybrid memory assembly, i.e., a memory die stack 500. Trade-off for PIM usually is between the speedup due to compute near-memory vs the area overhead/impact on memory density and leakage due to integration of PIM circuitry. The PIM circuitry 502 include processor or other logic circuitry integrated with memory circuitry 220/222 on a single IC die of the memory die stack 500. The PIM circuitry 502 contains local storage circuitry 506.

The local storage circuitry 506 of the PIM circuitry 502 may be FeRAM and/or embedded DRAM (eDRAM). Advantageously, the FeRAM and/or eDRAM based local storage circuitry 506 generally are low leakage logic-compatible storage as compared to local logic-based high leakage registers. This allows area scaling of PIM circuitry 502 and reduced leakage compared to conventional PIM using registers in the logic-based logical storage. Thus, the amount of processing in memory may be increased within the same IC die area allocated for the PIM circuitry 502.

This can also be used towards more fine-grained PIM (e.g., at a sub-bank level; currently PIM is performed at a bank level) or increased memory density due to reduced PIM area.

Referring first to FIG. 5A, the memory die stack 500 is shown disposed on top of a compute/processor IC die 108 and a memory-interface/controller IC die 120. The memory die stack 500 includes at least one HTMIC die 106, such as a non-volatile memory IC die, and a plurality of LTMIC dies 104, such as volatile memory dies. One of more of the LTMIC dies 104 have processing in memory (PIM) circuitry 502 with FeRAM and/or embedded DRAM based PIM local storage circuitry 506.

In FIG. 5B, a memory die stack 510 is shown disposed on top of a compute/processor IC die 108 and a memory-interface/controller IC die 120. The memory die stack 510 includes at least one HTMIC die 106, such as a non-volatile memory IC die, and a plurality of LTMIC dies 104, such as volatile memory dies. One of more of the LTMIC dies 104 have additional PIM circuitry 502 relative to FeRAM and/or embedded DRAM based PIM local storage circuitry 506 as compared to the memory die stack 500 of FIG. 5A.

In FIG. 5C, a memory die stack 520 is shown disposed on top of a compute/processor IC die 108 and a memory-interface/controller IC die 120. The memory die stack 520 includes at least one HTMIC die 106, such as a non-volatile memory IC die, and a plurality of LTMIC dies 104, such as volatile memory dies. One of more of the LTMIC dies 104 have fine grained PIM circuitry 502 with FeRAM and/or embedded DRAM based PIM local storage circuitry 506.

In FIG. 5D, a memory die stack 530 is shown disposed on top of a compute/processor IC die 108 and a memory-interface/controller IC die 120. The memory die stack 530 includes at least one HTMIC die 106, such as a non-volatile memory IC die, and a plurality of LTMIC dies 104, such as volatile memory dies. One of more of the LTMIC dies 104 has fine grained sub-bank level PIM circuitry 502 with FeRAM based PIM local storage circuitry 506. In an alternative hybrid approach, the plurality of LTMIC dies 104 includes DRAM IC memory dies stacked on top of one or more SRAM IC memory dies. The SRAM IC memory die(s) can be configured to function as a hardware managed cache for the DRAM IC memory dies, or as a part of the address space offering exceptionally low latency. In the exampled depicted in FIG. 5D, the HTMIC die 106 includes FeRAM memory arrays that allow more easy integration of PIM circuitry 502 in logic-compatible FeRAM circuitry of the HTMIC die 106. All of the above examples enable enhanced SoC performance and power efficiency.

What is claimed is:

1. A memory stack comprising:
a first memory IC die comprising memory and
a second memory IC die stacked on the first memory IC die, the second memory IC die comprising memory circuitry requiring refresh rates more frequent than that of the first memory IC die.

2. The memory stack of claim 1, wherein the memory circuitry of the first memory IC die is non-volatile memory circuitry.

3. The memory stack of claim 2, wherein the non-volatile memory circuitry is ferro-electric random-access memory (Fe RAM) or static random-access memory (SRAM) circuitry.

4. The memory stack of claim 3, wherein the memory circuitry of the second memory IC die is volatile memory circuitry

5. The memory stack of claim 4, wherein the volatile memory circuitry is dynamic random-access memory (DRAM) circuitry.

6. The memory stack of claim 1, further comprising:
a controller die stacked below and in contact with the first memory IC die.

7. The memory stack of claim 6, further comprising:
a processor die stacked below and in contact with the controller die, the processor die includes processor circuitry that communicates with memory circuitries of the first and second memory IC dies through controller circuitry of the controller IC die.

8. The memory stack of claim 1, wherein the first memory IC die includes controller circuitry.

9. The memory stack of claim 8, further comprising:
a processor die stacked below and in contact with the first memory IC die, the processor die includes processor circuitry that communicates with memory circuitries of the first and second memory IC dies through controller circuitry of the first memory IC die.

10. The memory stack of claim 1, further comprising:
a third memory IC die stacked on the second memory IC die, the third memory IC die comprising dynamic random-access memory (DRAM) circuitry.

11. The memory stack of claim 10, wherein the third memory IC die has a greater latency than the second memory IC die, and second memory IC die has a greater latency than the first memory IC die.

12. The memory stack of claim 10 further comprising:
first processing in memory (PIM) circuitry disposed in the second memory IC die; and
second PIM circuitry disposed in the third memory IC die.

13. The memory stack of claim 1, wherein the first memory IC die includes controller circuitry.

14. The memory stack of claim 13, further comprising:
a processor die stacked below and in contact with the first memory IC die, the processor die includes processor circuitry that communicates with memory circuitries of the first and second memory IC dies through the controller circuitry of the first memory IC die.

15. The memory stack of claim 14, further comprising:
a first buffer IC die disposed between the second memory IC die and the third memory IC die.
a fourth memory IC die stacked on the second memory IC die, the third memory IC die comprising dynamic random-access memory (DRAM) circuitry; and
a second buffer IC die disposed between the third memory IC die and the fourth memory IC die.

16. The memory stack of claim 1, further comprising:
a first buffer IC die disposed between the first memory IC die and the second memory IC die.

17. A memory stack comprising:
a first memory IC die comprising ferro-electric random-access memory (Fe RAM); and
a second memory IC die stacked on the first memory IC die, the second memory IC die comprising dynamic random-access memory (DRAM) circuitry.

18. The memory stack of claim 17, further comprising:
a controller die stacked below and in contact with the first memory IC die.

19. The memory stack of claim 18, further comprising:
a processor die stacked below and in contact with the controller die, the processor die includes processor circuitry that communicates with memory circuitries of the first and second memory IC dies through controller circuitry of the controller IC die.

20. A chip package comprising:
a package substrate; and
a memory stack stacked on the package substrate, the memory stack comprising:
a plurality of first memory IC dies stacked on a second memory IC die, the second memory IC die having ferro-electric random-access memory (FeRAM) circuitry and optionally controller circuitry, the second memory IC die stacked on the package substrate, the plurality of first memory IC dies including DRAM circuitry.
